(19) United States
(12) Patent Application Publication
(10) Pub. No.: US 2011/0075369 A1
(43) Pub. Date: Mar. 31, 2011

(54) ELECTRONIC DEVICE

(75) Inventors: Kuang-Chung Sun, Taipei City (TW); Ting-Chiang Huang, Taipei City (TW); Chiun-Peng Chen, Taipei City (TW); Chih-Kuang Chung, Taipei City (TW); Sheng-Chieh Hsu, Taipei City (TW); Wei-Yi Lin, Taipei City (TW)

(73) Assignee: INVENTEC CORPORATION, Taipei City (TW)

(21) Appl. No.: 12/684,237

(22) Filed: Jan. 8, 2010

(30) Foreign Application Priority Data
Sep. 29, 2009 (TW) 98133048

(51) Int. Cl. H05K 7/20

(52) U.S. Cl. 361/700

(57) ABSTRACT

An electronic device including a heat generation element, a heat dissipation plate, and a heat pipe is provided. The heat dissipation plate includes a top surface, a bottom surface, a pair of longitudinal side surfaces, and a pair of lateral side surfaces including a third side surface and a fourth side surface. The longitudinal side surfaces include first and second side surfaces. The lateral side surfaces include third and fourth side surfaces. The first, second, third and fourth side surfaces are connected to both the top surface and the bottom surface. The heat pipe is disposed in contact with the heat dissipation plate, and the heat pipe and the heat generation element are disposed on the bottom surface of the heat dissipation plate. The heat pipe is disposed on the heat dissipation plate and extension of the heat pipe is not beyond the first, second, third and fourth side surfaces.

### CROSS-REFERENCE TO RELATED APPLICATION

This application claims the priority benefit of Taiwan application serial no. 98133048, filed Sep. 29, 2009. The entirety of the above-mentioned patent application is hereby incorporated by reference herein and made a part of this specification.

### BACKGROUND OF THE INVENTION

1. Field of the Invention

The present invention relates to an electronic device, and more particularly, to an electronic device with a heat dissipation structure.

2. Description of Related Art

Following the development of technology, portable electronic devices such as notebook computers are being widely used in people's work and daily life because they can enhance the working efficiency and convenience in the daily life. In order to be easy to carry, the small size and light weight requirements have been continuously imposed on the notebook computers. At the same time, faster and faster computing and executing speed of the notebook computers have been continuously demanded. As a result, the internal electronic elements of the notebook computers generate more and more heat during operation. The heat is typically dissipated via a heat dissipation device consisting of a heat sink and a fan.

FIG. 1 illustrates an interior structure of a conventional notebook computer. Referring to FIG. 1, in the notebook computer 10, the heat generated by a system chip 11 (e.g. a central processing unit) is conducted to a heat sink 13 via a heat pipe 12 connected between the system chip 12 and the heat sink 13. The heat on the heat sink 13 is then taken off the notebook computer 10 via the fan 14. However, under the current trend that the notebook computers are being developed to be lighter, thinner, shorter and smaller, the heat dissipation structure using the fan 14 described above can no longer meet the heat dissipation requirements. What is needed, therefore, is an improved heat dissipation device that can quickly dissipate the heat.

### SUMMARY OF THE INVENTION

Accordingly, the present invention is directed to an electronic device in which a heat pipe and a heat generation element are disposed on a bottom surface of a heat dissipation plate.

The present invention is also directed to an electronic device in which a heat dissipation plate and a heat pipe are used to dissipate the heat of a system chip.

The present invention is also directed to an electronic device in which a keyboard support and a heat pipe are used to dissipate the heat of a heat generation element.

One embodiment of the present invention provides an electronic device including a heat generation element, a heat dissipation plate, and a heat pipe. The heat dissipation plate includes a top surface, a bottom surface, a pair of longitudinal side surfaces, and a pair of lateral side surfaces. The pair of longitudinal side surfaces includes a first side surface and a second side surface. The pair of lateral side surfaces includes a third side surface and a fourth side surface. The first side surface, the second side surface, the third side surface and the fourth side surface connected to both the top surface and the bottom surface. The heat pipe is disposed in contact with the heat dissipation plate, and the heat pipe and the heat generation element are disposed on the bottom surface of the heat dissipation plate. The heat pipe is disposed on the heat dissipation plate and extension of the heat pipe is not beyond the first side surface, the second side surface, the third side surface, and the fourth side surface.

Another embodiment of the present invention provides an electronic device including a base, a circuit board, a system chip, a heat dissipation plate, and a heat pipe. The circuit board is disposed on the base. The system chip is packaged on the circuit board. The heat dissipation plate is disposed on the base and in contact with the system chip. The heat pipe is disposed in contact with the heat dissipation plate.

Another embodiment of the present invention provides an electronic device including a bracket, a keyboard, a heat generation element, and a heat pipe. The keyboard is disposed on the bracket such that the bracket is for strutting the keyboard. The heat generation device is disposed in contact with the bracket. The heat pipe is disposed on the bracket.

According to one embodiment of the present invention, the heat pipe includes a first end and a second end. The heat generation element is disposed adjacent to the third side surface of the heat dissipation plate. The first end of the heat pipe is disposed adjacent to the heat generation element. The second end of the heat pipe is disposed away from the heat generation element and extends toward the fourth side surface of the heat dissipation plate.

According to one embodiment of the present invention, the heat dissipation plate includes a first section, a second section, and a connection section interconnecting the first section and the second section. The heat pipe includes a first end and a second end. The heat generation device is disposed on the first section. The first end of the heat pipe is disposed in contact with the first section and the second end of the heat pipe is disposed in contact with the second section.

According to one embodiment of the present invention, peripheries of the first section, the second section and the connection section of the heat dissipation plate define a notch or a through opening.

According to one embodiment of the present invention, the heat generation element and the heat pipe are disposed on the top surface and the bottom surface of the heat dissipation plate, respectively.

According to one embodiment of the present invention, the heat generation element and the heat pipe are both disposed on the top surface or the bottom surface of the heat dissipation plate.

According to one embodiment of the present invention, the heat pipe includes a first end and a second end. The system chip is disposed adjacent to the third side surface of the heat dissipation plate. The first end of the heat pipe is disposed adjacent to the system chip. The second end of the heat pipe is disposed away from the system chip and extends toward the fourth side surface of the heat dissipation plate.

According to one embodiment of the present invention, the heat pipe is disposed in contact with the heat generation element.

According to one embodiment of the present invention, the heat pipe is disposed in contact with the system chip.

In view of the foregoing, in embodiments of the present invention, the bracket or heat dissipation plate is disposed in contact with the heat generation element such that the heat generated by the heat generation element can be dissipated via the bracket or heat dissipation plate. In addition, the heat pipe is disposed on the bracket or heat dissipation plate, such that the heat conducted from the heat generation element to the bracket or heat dissipation plate can be uniformly distributed over the entire bracket or heat dissipation plate. A large amount of heat within the electronic device can thus be quickly removed by making the heat distribution uniform.

In order to make the aforementioned and other features and advantages of the present invention more comprehensible, embodiments accompanied with figures are described in detail below.

### BRIEF DESCRIPTION OF THE DRAWINGS

FIG. 1 illustrates an interior structure of a conventional notebook computer.

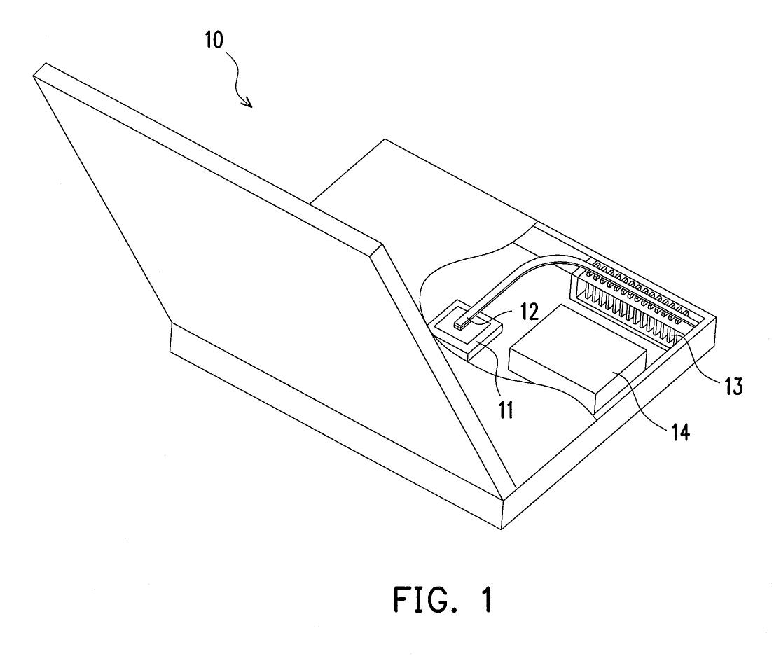

FIG. 2 illustrates an electronic device according to one embodiment of the present invention.

FIG. 3 is a partial exploded view of the electronic device of FIG. 2.

FIG. 4 is a partial perspective view of the electronic device of FIG. 2.

FIG. 5 illustrates the bracket of FIG. 3.

### DESCRIPTION OF THE EMBODIMENTS

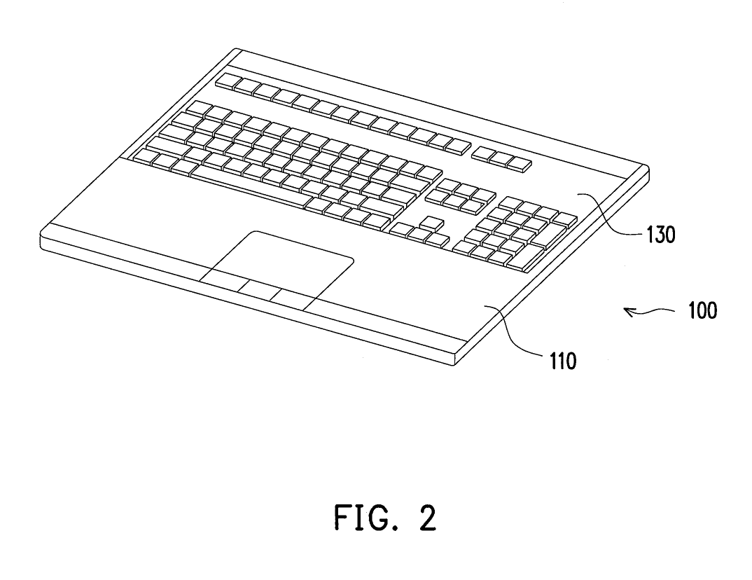

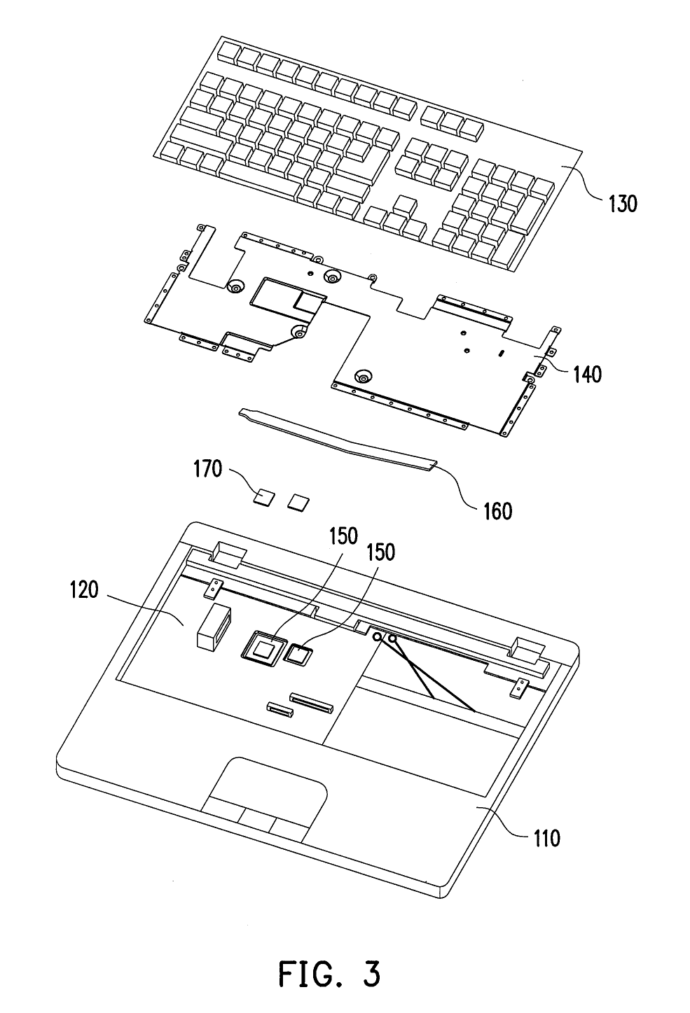

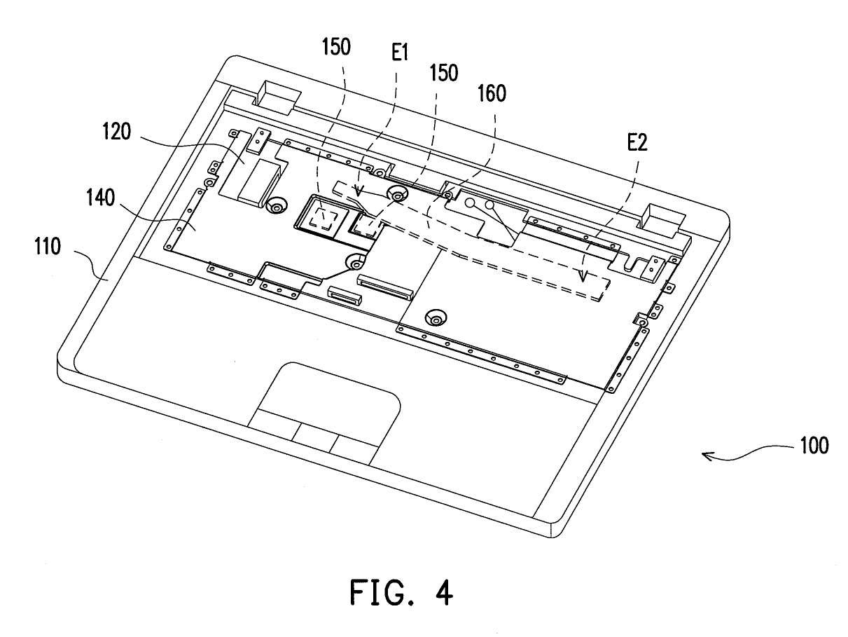

FIG. 2 illustrates an electronic device according to one embodiment of the present invention. FIG. 3 is a partial exploded view of the electronic device of FIG. 2. FIG. 4 is a partial perspective view of the electronic device of FIG. 2. Referring to FIGS. 2, 3 and 4, the electronic device 100 is, for example, a notebook computer and only a host of the notebook computer is partially illustrated herein. The electronic device 100 includes a housing 110, a circuit board 120, a keyboard 130, a bracket 140, at least one heat generation element 150, and a heat pipe 160. The bracket 140 is disposed in the housing 110 and the keyboard 130 is disposed on the bracket 140 such that the bracket 140 acts as a supporting structure for the keyboard 130.

The circuit board 120 is, for example, a motherboard of the notebook computer and is disposed between a bottom of the housing 110 and the bracket 140. The heat generation element 150 is, for example, a system chip packaged on the circuit board 120, such as, a central processing unit, a north bridge chip, or a south bridge chip. The heat generation element 150 may also be a high power electronic element such as a graphic chip. Only two heat generation elements 150 are illustrated in the present embodiment. The bracket 140 is in contact with the heat generation elements 150 and the heat pipe 160 is disposed on the bracket 140. Therefore, the heat generated by the heat generation elements 150 can be conducted and dissipated out of the electronic device 100 via the bracket 140 and the heat pipe 160.

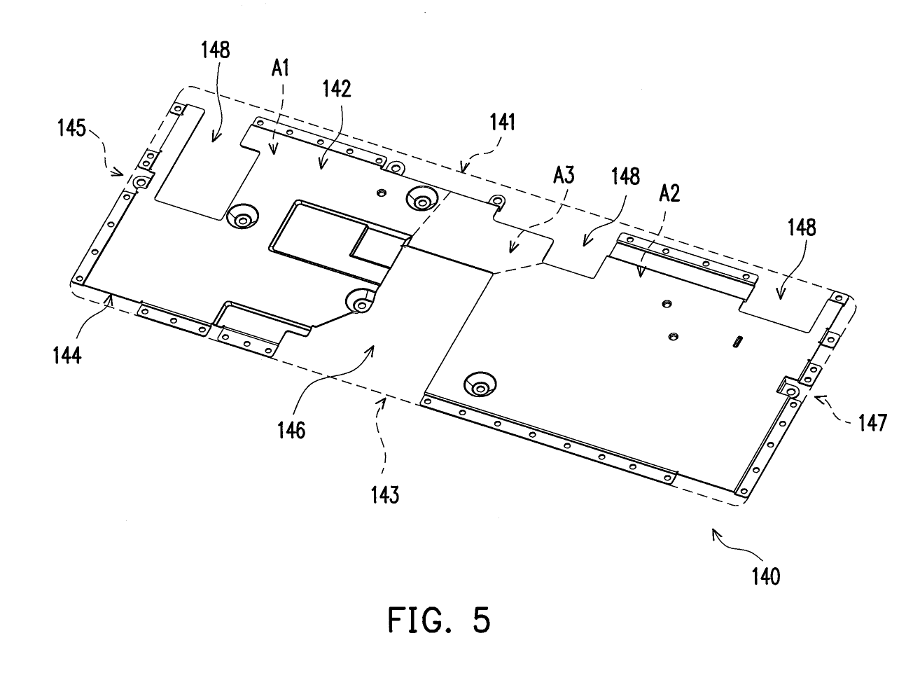

FIG. 5 illustrates the bracket of FIG. 3. Referring to FIG. 5, the bracket 140 includes a top surface 142, a bottom surface 144, a pair of longitudinal side surfaces 141, 143, and a pair of lateral side surfaces 145, 147. The longitudinal side surfaces 141, 143 include a first side surface 141 and a second side surface 143. The lateral side surfaces 145, 147 include a third side surface 145 and a fourth side surface 147. The first side surface 141, the second side surface 143, the third side surface 145 and the fourth side surface 147 are all connected between the top surface 142 and the bottom surface 144.

Referring to FIG. 4 and FIG. 5, in the present embodiment, both the heat pipe 160 and the heat generation element 150 are disposed on the bottom surface 144 of the bracket 140. Extension of the heat pipe 160 is not beyond the first side surface 141, the second side surface 143, the third side surface 145 and the fourth side surface 147, i.e., the heat pipe 160 is substantially disposed on the geometry plane of the bracket 140. In another embodiment not illustrated, the heat generation element 150 and the heat pipe 160 may be disposed on the top surface 142 and the bottom surface 144 of the bracket 140, respectively, according to actual requirements, which can likewise achieve the heat dissipation result of the present embodiment.

In addition, since the heat pipe 160 can be configured to have different curve structures according to actual requirements, when the heat pipe 160 and the heat generation element 150 are both disposed on the top surface 142 or bottom surface 144 of the bracket 140, the heat pipe 160 can also contact the heat generation element 150, such that the heat generation element 1500 can be cooled via the heat pipe 160 and the bracket 140 at the same time to increase the capabilities of the heat pipe 160 and the bracket 140 of dissipating the heat of the heat generation element 150.

Specifically, as shown in FIG. 3 and FIG. 5, the bracket 140 includes a first section A1, a second section A2, and a connection section A3. The connection section A3 is interconnected between the first section A1 and the second section A2 and has a surface area substantially smaller than a surface area of the first section A1 and a surface area of the second section A2. In addition, peripheries of the first section A1, the second section A2 and the connection section A3 define a first notch 146 for allowing a keyboard cable (not shown) to pass through the first notch 146 to connect the keyboard 130 above the bracket 140 with the circuit board 120 below the bracket 140.

In addition, the bracket 140 has a plurality of second notches 148 which are distributed in the first section A1, the second section A2 or the connection section A3. In addition to acting as a connection channel between the top and bottom surfaces 142 and 144 of the bracket 140 as the first notch 146, the second notches 148 can also be used as receiving spaces for receiving internal elements (e.g. antenna, pivot or the like) within the housing 110.

On the other hand, the first section A1 is disposed adjacent to the third side surface 145 of the bracket 140, and the second section A2 is disposed adjacent to the fourth side surface 147 of the bracket 140. The heat generation element 150 is in contact with the first section A1 and, therefore, the heat generated by the heat generation element 150 is distributed over the entire first section A1 and then conducted from the first section A1 to the second section A2 via the connection section A3. However, the surface area of the connection area A3 is smaller than the surface area of the first section A1 and the surface area of the second section A2. In other words, the heat of the first section A1 needs to pass the first notch 146 in order to be conducted to the second section A2. This hinders the heat transfer and, as a result, causes a heat concentration on the first section A1 and the connection section A3, which in effect reduces the heat dissipation area for dissipating heat of the heat generation element 150.

As shown in FIG. 4 and FIG. 5, in order for the heat to be uniformly distributed over the entire bracket 140 such that the heat generation element 150 can be cooled via the entire bracket 140, a heat pipe 160 is disposed on the bracket 140. The heat pipe 160 includes a first end E1 and a second end E2. The first end E1 of the heat pipe 160 contacts the first section A1 of the bracket 140. The heat pipe 160 extends from the third side surface 145 toward the fourth side surface 147 of the bracket 140. The heat pipe 160 extends over the connection section A3 such that the second end E2 of the heat pipe 160 contacts the second section A2 of the bracket 140.

Therefore, the heat of the heat generation element 150 can be conducted to the second end E2 positioned away from the heat generation element 150 through the first end E1 of the heat pipe 160. In other words, the heat of the first section A1 can be conducted to the connection area A3 and the second section A2 through the heat pipe 160, such that the heat can be uniformly distributed over the entire bracket 140 thus increasing the heat dissipation area to avoid the heat concentration on the first section A1 and improve the heat dissipation result.

On the other hand, as shown in FIG. 3, in the present embodiment, the electronic device 100 further includes a thermally conductive pad 170 disposed between the bracket 140 and the heat generation element 150. In addition to conducting the heat generated by the heat generation element 150 to the bracket 140, the thermally conductive pad 170 can also absorb the assembly tolerance of the bracket 140 and heat generation element 150 to reduce the fabrication cost of relevant elements within the housing 110 and increase the assembly yield of assembling the bracket 140 to the housing 110.

In summary, in the present invention, the bracket for supporting the keyboard is in contact with the heat generation element. Therefore, the heat generated by the heat generation element can be conducted and dissipated out of the electronic device via the bracket. In addition, the heat generated by the heat generation element can be conducted from one section to another section of the bracket via the heat pipe disposed on the bracket, which allows the heat to be uniformly distributed over the entire bracket. A large amount of heat within the electronic device can be quickly removed by making the heat distribution uniform.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device comprising
a heat generation element;
a heat dissipation plate comprising a top surface, a bottom surface, a pair of longitudinal side surfaces, and a pair of lateral side surfaces, the pair of longitudinal side surfaces comprising a first side surface and a second side surface, the pair of lateral side surfaces comprising a third side surface and a fourth side surface, the first side surface, the second side surface, the third side surface and the fourth side surface connected to both the top surface and the bottom surface; and
a heat pipe disposed in contact with the heat dissipation plate, wherein the heat pipe and the heat generation element are disposed on the bottom surface of the heat dissipation plate, and extension of the heat pipe is not beyond the first side surface, the second side surface, the third side surface, and the fourth side surface.

2. The electronic device according to claim 1, wherein the heat pipe comprises a first end and a second end, the heat generation element is disposed adjacent to the third side surface of the heat dissipation plate, the first end of the heat pipe is disposed adjacent to the heat generation element, and the second end of the heat pipe is disposed away from the heat generation element and extends toward the fourth side surface of the heat dissipation plate.

3. The electronic device according to claim 1, wherein the heat dissipation plate comprises a first section, a second section, and a connection section interconnecting the first section and the second section, the heat pipe comprises a first end and a second end, the heat generation device is disposed on the first section, the first end of the heat pipe is disposed in contact with the first section and the second end of the heat pipe is disposed in contact with the second section.

4. The electronic device according to claim 3, wherein peripheries of the first section, the second section and the connection section of the heat dissipation plate define a notch or a through opening.

5. An electronic device comprising:
a base;
a circuit board disposed on the base;
a system chip packaged on the circuit board;
a heat dissipation plate disposed on the base and in contact with the system chip; and
a heat pipe disposed in contact with the heat dissipation plate.

6. The electronic device according to claim 5, wherein the heat dissipation plate comprises a top surface, a bottom surface, a pair of longitudinal side surfaces, and a pair of lateral side surfaces, the pair of longitudinal side surfaces comprises a first side surface and a second side surface, the pair of lateral side surfaces comprises a third side surface and a fourth side surface, the first side surface, the second side surface, the third side surface and the fourth side surface are connected to both the top surface and the bottom surface, the heat pipe is disposed on the heat dissipation plate and extension of the heat pipe is not beyond the first side surface, the second side surface, the third side surface, and the fourth side surface.

7. The electronic device according to claim 6, wherein the heat generation element and the heat pipe are disposed on the top surface and the bottom surface of the heat dissipation plate, respectively.

8. The electronic device according to claim 6, wherein the heat generation element and the heat pipe are both disposed on the top surface or the bottom surface of the heat dissipation plate.

9. The electronic device according to claim 6, wherein the heat pipe comprises a first end and a second end, the system chip is disposed adjacent to the third side surface of the heat dissipation plate, the first end of the heat pipe is disposed adjacent to the system chip, and the second end of the heat pipe is disposed away from the system chip and extends toward the fourth side surface of the heat dissipation plate.

10. The electronic device according to claim 5, wherein the heat dissipation plate comprises a first section, a second section, and a connection section interconnecting the first section and the second section, the heat pipe comprises a first end and a second end, the heat generation device is disposed on the first section, the first end of the heat pipe is disposed in contact with the first section and the second end of the heat pipe is disposed in contact with the second section.

11. The electronic device according to claim 10, wherein peripheries of the first section, the second section and the connection section of the heat dissipation plate define a notch or a through opening.

12. The electronic device according to claim 5, wherein the heat pipe is disposed in contact with the system chip.

13. An electronic device comprising:
a bracket;
a keyboard disposed on the bracket such that the bracket is for strutting the keyboard;
a heat generation device disposed in contact with the bracket; and
a heat pipe disposed on the bracket.

14. The electronic device according to claim 13, wherein the bracket comprises a top surface, a bottom surface, a pair of longitudinal side surfaces, and a pair of lateral side surfaces, the pair of longitudinal side surfaces comprises a first side surface and a second side surface, the pair of lateral side surfaces comprises a third side surface and a fourth side surface, the first side surface, the second side surface, the third side surface and the fourth side surface are connected to both the top surface and the bottom surface, and extension of the heat pipe is not beyond the first side surface, the second side surface, the third side surface, and the fourth side surface.

15. The electronic device according to claim 14, wherein the heat generation element and the heat pipe are disposed on the top surface and the bottom surface of the bracket, respectively.

16. The electronic device according to claim 14, wherein the heat generation element and the heat pipe are both disposed on the top surface or the bottom surface of the bracket.

17. The electronic device according to claim 14, wherein the heat pipe comprises a first end and a second end, the heat generation element is disposed adjacent to the third side surface of the bracket, the first end of the heat pipe is disposed adjacent to the heat generation element, and the second end of the heat pipe is disposed away from the heat generation element and extends toward the fourth side surface of the bracket.

18. The electronic device according to claim 13, wherein the bracket comprises a first section, a second section, and a connection section interconnecting the first section and the second section, the heat pipe comprises a first end and a second end, the heat generation device is disposed on the first section, the first end of the heat pipe is disposed in contact with the first section and the second end of the heat pipe is disposed in contact with the second section.

19. The electronic device according to claim 18, wherein peripheries of the first section, the second section and the connection section of the bracket define a notch or a through opening.

20. The electronic device according to claim 13, wherein the heat pipe is disposed in contact with the system chip.
